(19) United States
(12) Patent Application Publication
(10) Pub. No.: US 2018/0160543 A1
(43) Pub. Date: Jun. 7, 2018

(54) MANUFACTURING METHOD OF CIRCUIT BOARD AND STRUCTURE THEREOF

(71) Applicant: Unimicron Technology Corp., Taoyuan City (TW)

(72) Inventors: Po-Hsuan Liao, Taoyuan City (TW); Chi-Min Chang, Taoyuan City (TW); Cheng-Po Yu, Taoyuan City (TW)

(73) Assignee: Unimicron Technology Corp., Taoyuan City (TW)

(21) Appl. No.: 15/430,556

(22) Filed: Feb. 13, 2017

(30) Foreign Application Priority Data
Dec. 6, 2016 (TW) 105140170

(51) Int. Cl. H05K 3/20; H05K 3/38; H05K 1/11

(52) U.S. Cl. CPC H05K 3/20; H05K 2203/166; H05K 1/115; H05K 3/38

(57) ABSTRACT

A manufacturing method of a circuit board including the following steps is provided. A first patterned circuit layer is formed on a surface of a circuit substrate, and the first patterned circuit layer exposes a portion of the surface of the circuit substrate. A patterned glue layer is formed on the portion of the surface of the circuit substrate exposed by the first patterned circuit layer. A second patterned circuit layer is transfer-printed on the corresponding patterned glue layer. In addition, a structure of the circuit board is also mentioned.

### CROSS-REFERENCE TO RELATED APPLICATION

This application claims the priority benefit of Taiwan application serial no. 105140170, filed on Dec. 6, 2016. The entirety of the above-mentioned patent application is hereby incorporated by reference herein and made a part of this specification.

### BACKGROUND OF THE INVENTION

### Field of the Invention

The invention relates to a manufacturing method of a circuit board and a structure thereof, and particularly relates to a manufacturing method of a circuit board having a thick metal fine circuit structure and a structure thereof.

### Description of Related Art

In a process of printing a circuit board, to manufacture fine line patterns of the circuit board, a modified semi-additive process (MSAP) is often used to manufacture a circuit layer having a line width of 40 microns (μm) or less on a circuit substrate. However, the aforementioned process requires high investment in equipments and materials, such that the material and production costs required for the manufacturing process of printing the circuit board are greatly increased. Additionally, a thick metal circuit layer (e.g., a thick copper layer) is difficult to be manufactured by the aforementioned modified semi-additive process, such that the application of the thick metal circuit layer in the production of the thin circuit structure is restricted.

### SUMMARY OF THE INVENTION

The invention provides a manufacturing method of a circuit board, which manufactures a structure of the circuit board having a thick metal fine circuit layer by a circuit transfer-printing method.

The invention provides a structure of a circuit board having a patterned thick metal fine circuit layer with different line widths disposed on a circuit substrate.

The invention provides a manufacturing method of a circuit board including the following steps. A first patterned circuit layer is formed on a surface of a circuit substrate, and the first patterned circuit layer exposes a portion of the surface of the circuit substrate. A patterned glue layer is formed on the portion of the surface of the circuit substrate exposed by the first patterned circuit layer. A second patterned circuit layer is transfer-printed on the corresponding patterned glue layer.

The invention provides a structure of a circuit board including a circuit substrate, a first patterned circuit layer, a patterned glue layer, and a second patterned circuit layer. The first patterned circuit layer is disposed on a surface of the circuit substrate and exposes a portion of the surface of the circuit substrate. The patterned glue layer is disposed on the portion of the surface of the circuit substrate exposed by the first patterned circuit layer. The second patterned circuit layer is correspondingly disposed on the patterned glue layer. Additionally, a line width of the second patterned circuit layer is smaller than a line width of the first patterned circuit layer.

According to an embodiment of the invention, the manufacturing method of the circuit board further includes forming the second patterned circuit layer on a release layer before the second patterned circuit layer is transfer-printed on the corresponding patterned glue layer.

According to an embodiment of the invention, the circuit substrate has first alignment patterns, and the release layer has second alignment patterns. Also, before the second patterned circuit layer is transfer-printed on the corresponding patterned glue layer, the first alignment patterns are aligned with the second alignment patterns.

According to an embodiment of the invention, the manufacturing method of the circuit board further includes forming a dielectric layer on the circuit substrate. The dielectric layer covers on the first patterned circuit layer and the second patterned circuit layer and fills between the first patterned circuit layer and the second patterned circuit layer.

According to an embodiment of the invention, a method of forming the patterned glue layer includes a screen printing method or an ink-jet printing method.

According to an embodiment of the invention, the surface of the first patterned circuit layer and the surface of the second patterned circuit layer are aligned with each other.

According to an embodiment of the invention, the line width of the second patterned circuit layer is smaller than the line width of the first patterned circuit layer.

According to an embodiment of the invention, the line width of the first patterned circuit layer is larger than or equal to a line spacing between circuits of the first patterned circuit layer.

Based on the above, in the manufacturing method of the circuit board of the embodiments of the invention, the first patterned circuit layer may be formed on the circuit substrate. Next, the patterned glue layer may be formed on the portion of the surface of the circuit substrate exposed by the first patterned circuit layer. Then, the second patterned circuit layer may be correspondingly formed on the patterned glue layer by a transfer-printing method. Thus, in the embodiments of the invention, the first patterned circuit layer and the second patterned circuit layer may be respectively formed on the circuit substrate in different manufacturing methods. Particularly, the second patterned circuit layer is formed on the circuit substrate by a transfer-printing method, such that the second patterned circuit layer may have a smaller line width than the first patterned circuit layer, and the line spacing between the first patterned circuit layer and the second patterned circuit layer is decreased.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic structural view of a circuit board according to an embodiment of the invention.

FIG. 2 is a schematic structural view of a circuit board according to another embodiment of the invention.

FIG. 3A to FIG. 3I are schematic flow diagrams of a manufacturing method of the circuit board of FIG. 1 and FIG. 2.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

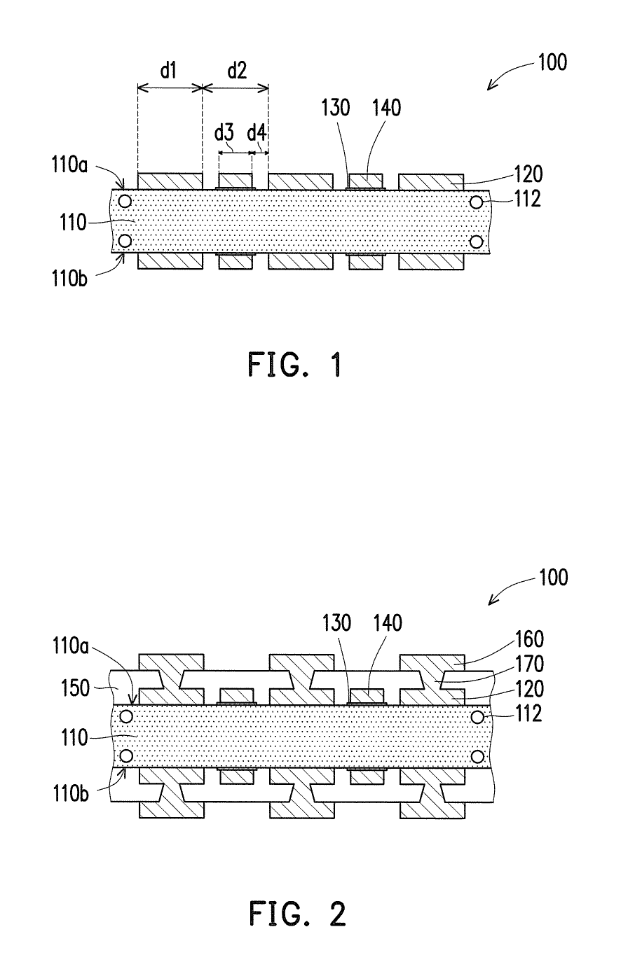

FIG. 1 is a schematic view of a structure of a circuit board according to an embodiment of the invention. In the embodiment, a circuit board 100 includes a circuit substrate 110, a first patterned circuit layer 120, a patterned glue layer 130, and a second patterned circuit layer 140. As shown in FIG. 1, in the embodiment, the first patterned circuit layer 120 may be formed on an upper surface 110a and a lower surface 110b of the circuit substrate 110 simultaneously. Additionally, the patterned glue layer 130 is disposed on a portion of the circuit substrate 110 exposed by the first patterned circuit layer 120. For example, the patterned glue layer 130 may be disposed in a gap between circuits of the first patterned circuit layer 120. Furthermore, the second patterned circuit layer 140 is correspondingly disposed on the patterned glue layer 130.

As shown in FIG. 1, a line spacing d2 between the circuits of the first patterned circuit layer 120 is larger than or equal to a line width d1 of the first patterned circuit layer 120. For example, a ratio of the line spacing d2 between the circuits of the first patterned circuit layer 120 to the line width d1 of the first patterned circuit layer 120 is in a range of 1 to 5. In the embodiment, a sum of line spacings d4 between two sides of the circuit of the second patterned circuit layer 140 and the first patterned circuit layer 120 respectively and a line width d3 of the second patterned circuit layer 140 is equal to the line spacing d2 between the circuits of the first patterned circuit layer 120 itself. In the embodiment, a ratio of the line width d3 of the second patterned circuit layer 140 to the line width d1 of the first patterned circuit layer 120 is in a range of 0.8 to 1.2, for example. Additionally, the line spacing d4 between the first patterned circuit layer 120 and the second patterned circuit layer 140 is smaller than the line width d3 of the second patterned circuit layer 140.

For example, the line width d1 of the first patterned circuit layer 120 may be smaller than 30 microns. Furthermore, the line spacing d4 between the first patterned circuit layer 120 and the second patterned circuit layer 140 may be smaller than or equal to 10 microns.

Additionally, in the embodiment, a ratio of a thickness of the first patterned circuit layer 120 to a thickness of the second patterned circuit layer 140 is in a range of 0.8 to 1.2, for example. In a general embodiment, a thickness of the glue layer 130 in FIG. 1 is extremely thin compared with the thickness of the second patterned circuit layer 140. Thus, the thickness of the second patterned circuit layer 140 may be approximately equal to the thickness of the first patterned circuit layer 120. In the embodiment, the thickness of the first patterned circuit layer 120 is larger than 50 microns, for example.

Therefore, in the embodiment, on the one hand, the circuits of the first patterned circuit layer 120 and the second patterned circuit layer 140 having a larger thickness may be formed on the circuit substrate 110. On the other hand, the second patterned circuit layer 140 may have a narrower line width d3 compared with the first patterned circuit layer. Additionally, compared with the circuit layer formed by a single patterning process, the first patterned circuit layer 120 and the second patterned circuit layer 140 may have a narrower line spacing d4 (e.g., smaller than 10 microns) therebetween.

Referring to FIG. 1 again, in the embodiment, the circuit substrate 110 further has a first alignment mark 112, so as to perform the alignment between a screen plate and the circuit substrate 110 when the patterned glue layer 130 is formed by a screen printing method, for example. Thereby, the alignment accuracy formed by the screen printing method is enhanced. Additionally, in the embodiment, the patterned glue layer 130 may also be formed by an ink-jet printing method.

FIG. 2 is a schematic view of a structure of a circuit board according to another embodiment of the invention. The difference between the present embodiment and the embodiment of FIG. 1 is that a dielectric layer 150 may be further formed above the first patterned circuit layer 120 and the second patterned circuit layer 140 on the circuit substrate 110. The dielectric layer 150 covers the first patterned circuit layer 120 and the second patterned circuit layer 140 and fills therebetween. Additionally, a third patterned circuit layer 160 may be formed on the dielectric layer 150 corresponding to the first patterned dielectric layer 120. Furthermore, a conductive via 170 may be Ruined in the dielectric layer 150 and penetrate the dielectric layer 150, so as to be electrically connected to the third patterned circuit layer 160 disposed on a surface of the dielectric layer 150 and the first patterned circuit layer 120 covered below the dielectric layer 150. In the embodiment, the dielectric layer 150, the conductive via 170 penetrating therein, and the third patterned circuit layer 160 may be repeatedly stacked above the first patterned circuit layer 120 and the second patterned circuit layer 140, so as to form the circuit board 100 having a multilayer laminated structure.

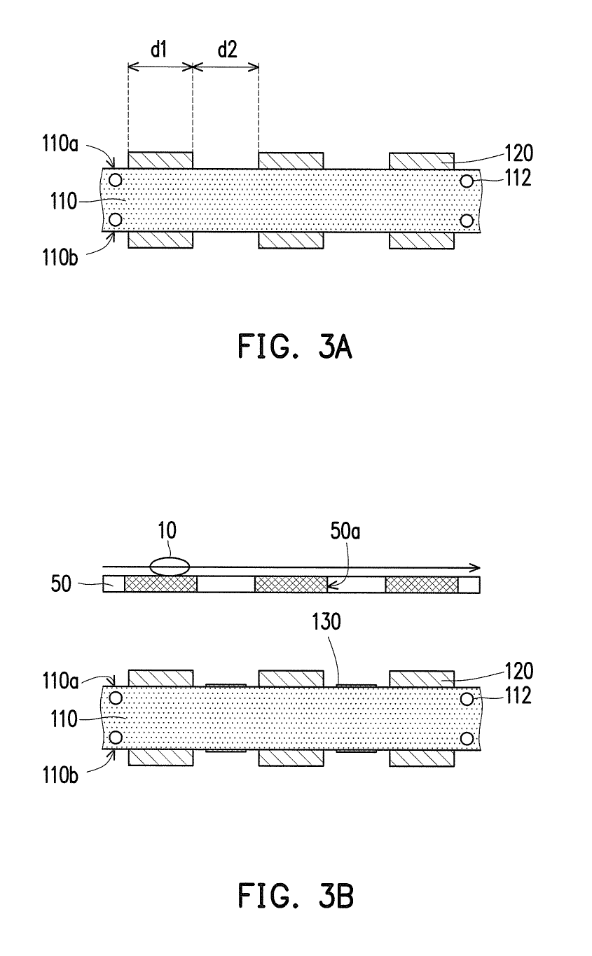

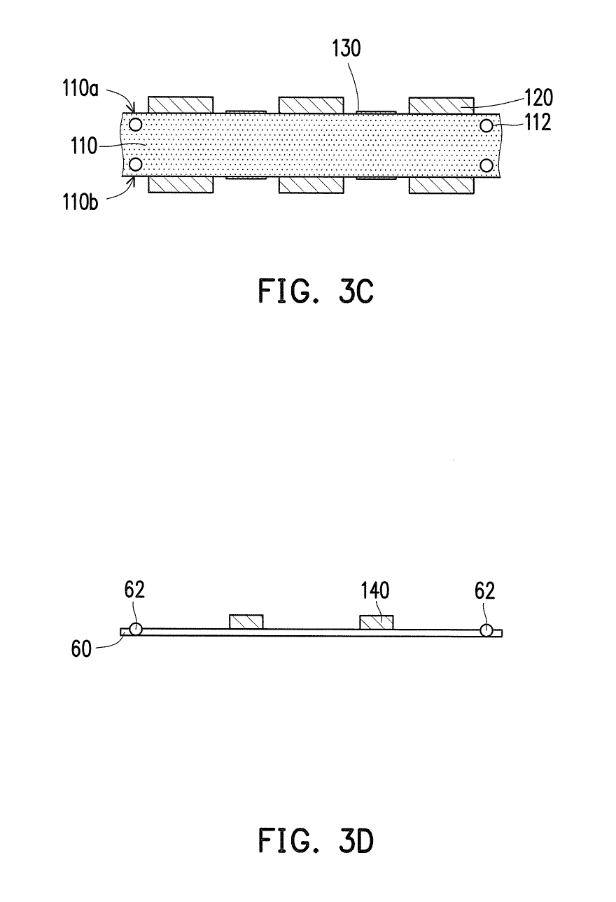

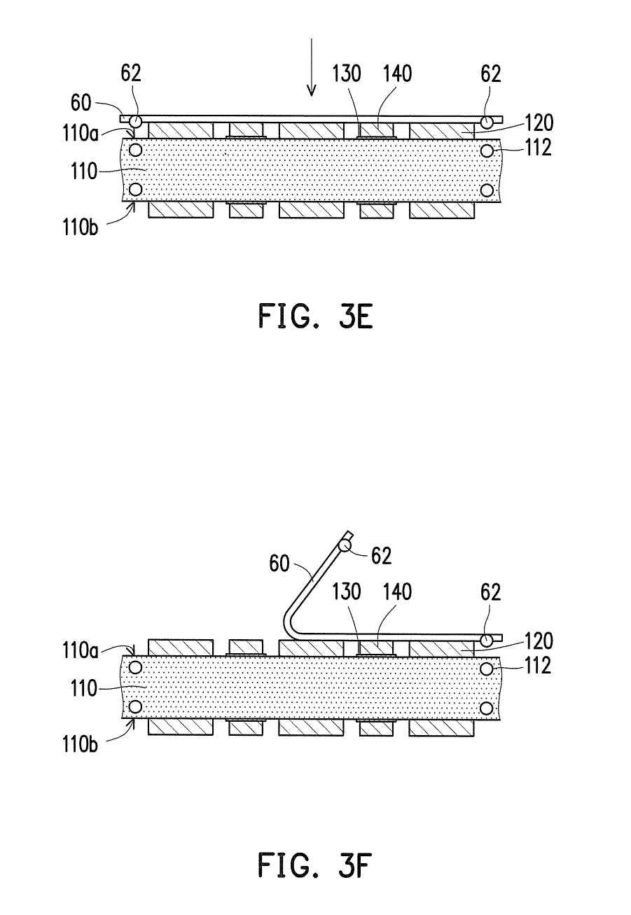

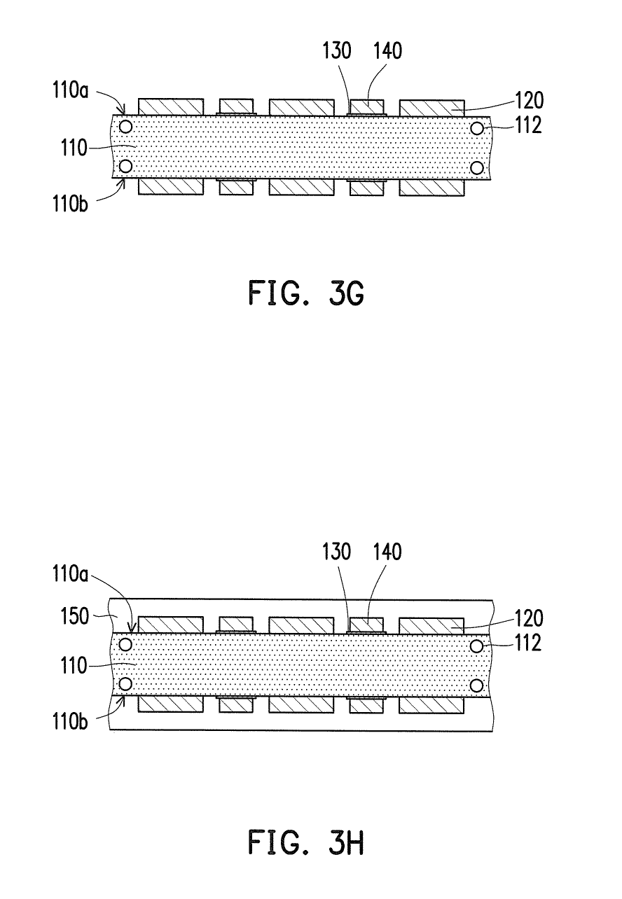

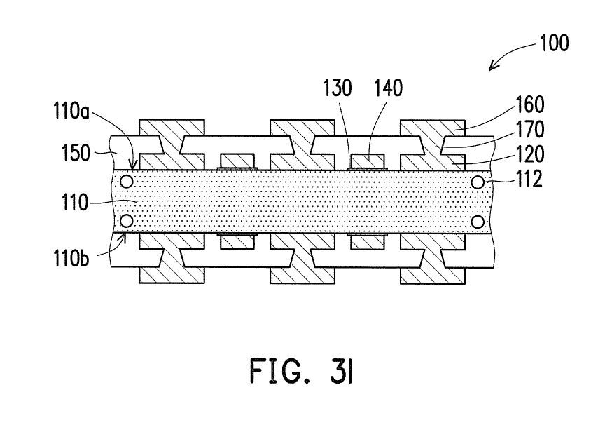

FIG. 3A to FIG. 3I are schematic flow diagrams of a manufacturing method of the circuit board of FIG. 1 and FIG. 2. In the embodiment, a method of forming the circuit board 100 includes the following steps. As shown in FIG. 3A, the first patterned circuit layer 120 is respectively formed at the upper surface 110a and the lower surface 110b of the circuit substrate 110, wherein the ratio of the line spacing d2 between the circuits of the first patterned circuit layer 120 to the line width d1 of the circuits is in a range of 1 to 5. In general, the ratio of the line spacing d2 to the line width d1 may be 3. Then, referring to FIG. 3B, on the portion of the surface of the circuit substrate 110 exposed by the first patterned circuit layer 120 (i.e., the gap between the circuits of the first patterned circuit layer 120 as shown in FIG. 3B), the patterned glue layer 130 is formed by a screen printing method or an ink-jet printing method, for example.

Specifically, as shown in FIG. 3B, in the embodiment, an adhesive 10 may be screen printed between the circuits of the first patterned circuit layer 120 through a screen plate 50. The adhesive 10 may be coated along the direction of the arrow in FIG. 3B and injected to a portion of the upper surface 110a between the circuits of the first patterned circuit layer 120 through a mesh opening 50a of the screen plate 50, so as to form the patterned glue layer 130 at the upper surface 110a of the circuit substrate 110. Thus, the patterned glue layer 130 may be exposed in the gap between the circuits of the first patterned circuit layer 120. Additionally, the steps the same as the aforementioned screen printing process may be repeated on the lower surface 110b of the circuit substrate 110, so as to form the patterned glue layer 130 on the lower surface 110b of the circuit substrate 110.

Referring to FIG. 3C, after the patterned glue layer 130 is formed, the screen plate 50 may be removed to continue the following process steps. Then, referring to FIG. 3D, the second patterned circuit layer 140 may be formed on a release layer 60 by a laser patterning process method first, for example. Additionally, as shown in FIG. 3D, the release layer 60 has second alignment patterns 62 to provide for performing the alignment of the release layer 60 and the circuit substrate 110.

Then, as shown in FIG. 3E, the second patterned circuit layer 140 on the release layer 60 is transfer-printed onto the upper surface 110a of the circuit substrate 110 along the direction of the arrow, and the same step is repeated on the lower surface 110b of the circuit substrate 110. Specifically, before the aforementioned transfer-printing process is performed, the release layer 60 may use an image alignment method, for example, to perform the alignment of the second alignment pattern 62 and the first alignment pattern 112 on the circuit substrate 110. Then, the second patterned circuit layer 140 on the release layer 60 may be correspondingly disposed on the patterned glue layer 130, such that the second patterned circuit layer 140 is attached on the portion of the surface of the circuit substrate 110 exposed between the circuits of the first patterned circuit layer 120 through the patterned glue layer 130.

Then, as shown in FIG. 3F, the release layer 60 may be removed by a heating or ultraviolet irradiation method. In the embodiment, since an adhesive force of the adhesive 10 of the patterned glue layer 130 to the second patterned circuit layer 140 is larger than an adhesive force between the release layer 60 and the second patterned circuit layer 140, the release layer 60 can be easily removed from the surface of the second patterned circuit layer 140 after heating or ultraviolet irradiating. Also, it does not cause the phenomenon of peeling of the second patterned circuit layer 140 on the surface of the circuit substrate 110.

As shown in FIG. 3G, after the release layer 60 is removed, the fabrication of the first patterned circuit layer 120 and the second patterned circuit layer 140 on the upper surface 110a and the lower surface 110b of the circuit substrate 110 is completed.

In the embodiment, the first patterned circuit layer 120 and the second patterned circuit layer 140 having different line widths can be formed on the circuit substrate 110 by the aforementioned manufacturing method, and the first and the second patterned circuit layers 120 and 140 are made by a metal material (e.g., copper), for example. Specifically, as shown in FIG. 1 and FIG. 3G, the ratio of the line width d3 of the second patterned circuit layer 140 to the line width d1 of the first patterned circuit layer 120 is in a range of 0.8 to 1.2, for example, and the ratio of the thickness of the first patterned circuit layer 120 to the thickness of the second patterned circuit layer 140 is in a range of 0.8 to 1.2, for example. Additionally, the line width of the first patterned circuit layer 120 is smaller than 30 microns, for example, and the gap between the first patterned circuit layer 120 and the second patterned circuit layer 140 is smaller than 20 microns, for example. In other words, in comparison with the circuit layer formed by a single patterning process step, a metal circuit layer having a narrower line width and line spacing and still having a larger line thickness (e.g., larger than 50 microns) can be manufactured by the process method of the embodiment, which overcomes the shortcomings of a general modified semi-additive process which is not conducive to the production of a thick metal fine circuit layer.

Referring to FIG. 3G, the dielectric layer 150 may be further formed above the first patterned circuit layer 120 and the second patterned circuit layer 140 which are completed. The dielectric layer 150 covers the first patterned circuit layer 120 and the second patterned circuit layer 140 and fills the gap therebetween. In the embodiment, a composition material of the dielectric layer 150 is a photo imagable dielectric (PID) resin, for example, but is not limited thereto.

Then, as shown in FIG. 3I, in the embodiment, a plurality of through vias may be formed corresponding to the first patterned circuit layer 120 by a mechanical drilling method or a laser drilling method in the dielectric layer 150, and the conductive vias 170 are formed by performing metal layer plating and etching processes in the through vias. Additionally, the third patterned circuit layer 160 may be formed on the dielectric layer 150 corresponding to the first patterned dielectric layer 120 and the conductive vias 170. The first patterned circuit layer 120 is electrically connected to the third patterned circuit layer 160 through the conductive vias 170. In the embodiment, the manufacturing methods of the dielectric layer 150, the conductive via 170, and the third patterned circuit layer 160 may be repeatedly applied onto the first patterned circuit layer 120 and the second patterned circuit layer 140, so as to form the circuit board 100 having a repeated laminated structure.

In summary, in the manufacturing method of the circuit board of the embodiments of the invention, the first patterned circuit layer and the second patterned circuit layer are respectively formed on the circuit substrate in different manufacturing methods. The second patterned circuit layer may be formed on the circuit substrate having the first patterned circuit layer formed thereon by a transfer-printing method. Since the second patterned circuit layer is formed on the circuit substrate by a transfer-printing method, the first and the second patterned circuit layers may have a smaller line spacing therebetween compared with the patterned circuit layer formed by a single patterning process step. Additionally, the manufacturing method of the circuit board of the embodiments of the invention makes the thickness of the circuit of the first patterned circuit layer and the second patterned circuit layer may not be limited to the line spacing therebetween, such that the circuit structure of the circuit board can still maintain a larger thickness of the circuit while the line spacing is decreased. Thus, the manufacturing method of the circuit board of the embodiments of the invention can be applied to the production of the circuit board having the thick metal fine circuit structure.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

1. A manufacturing method of a circuit board, comprising:
forming a first patterned circuit layer on a surface of a circuit substrate, and the first patterned circuit layer exposing a portion of the surface of the circuit substrate;
forming a patterned glue layer on the portion of the surface of the circuit substrate exposed by the first patterned circuit layer; and
transfer-printing a second patterned circuit layer on the corresponding patterned glue layer.

2. The manufacturing method of the circuit board according to claim 1, further comprising forming the second patterned circuit layer on a release layer before transfer-printing the second patterned circuit layer on the corresponding patterned glue layer.

3. The manufacturing method of the circuit board according to claim 2, wherein the circuit substrate has a plurality of first alignment patterns, the release layer has a plurality of second alignment patterns, and before transfer-printing the second patterned circuit layer on the corresponding patterned glue layer, the first alignment patterns are aligned with the second alignment patterns.

4. The manufacturing method of the circuit board according to claim 1, further comprising forming a dielectric layer on the circuit substrate, wherein the dielectric layer covers on the first patterned circuit layer and the second patterned circuit layer and fills between the first patterned circuit layer and the second patterned circuit layer.

5. The manufacturing method of the circuit board according to claim 1, wherein a method of forming the patterned glue layer comprises a screen printing method or an ink-jet printing method.

6. The manufacturing method of the circuit board according to claim 1, wherein a ratio of a thickness of the first patterned circuit layer to a thickness of the second patterned circuit layer is in a range of 0.8 to 1.2.

7. The manufacturing method of the circuit board according to claim 1, wherein a ratio of a line width of the second patterned circuit layer to a line width of the first patterned circuit layer is in a range of 0.8 to 1.2.

8. A structure of a circuit board, comprising:
a circuit substrate;
a first patterned circuit layer, disposed on a surface of the circuit substrate and exposing a portion of the surface of the circuit substrate;
a patterned glue layer, disposed on the portion of the surface of the circuit substrate exposed by the first patterned circuit layer; and
a second patterned circuit layer, correspondingly disposed on the patterned glue layer, wherein a ratio of a line width of the second patterned circuit layer to a line width of the first patterned circuit layer is in a range of 0.8 to 1.2.

9. The structure of the circuit board according to claim 8 wherein a ratio of a thickness of the first patterned circuit layer to a thickness of the second patterned circuit layer is in a range of 0.8 to 1.2.

10. The structure of the circuit board according to claim 8 wherein a ratio of a line spacing between circuits of the first patterned circuit layer to the line width of the first patterned circuit layer is in a range of 1 to 5.
